(19) United States
(12) Patent Application Publication
(10) Pub. No.: US 2014/0000847 A1
(43) Pub. Date: Jan. 2, 2014

(54) HIGH EFFICIENCY TIER IV COOLING SYSTEM ARCHITECTURE AND COOLING UNIT FOR FAULT TOLERANT COMPUTER ROOM AIR CONDITIONER (CRAC) SYSTEMS

(71) Applicants: Swanson Rink, Inc., Denver, CO (US); ViaWest, Inc., Greenwood Village, CO (US)

(72) Inventors: David J. Leonard, Superior, CO (US); Todd A. Gale, Larkspur, CO (US); Gary W. Orazio, Centennial, CO (US)

(21) Appl. No.: 13/924,349

(22) Filed: Jun. 21, 2013

Related U.S. Application Data
(60) Provisional application No. 61/665,734, filed on Jun. 28, 2012.

(51) Int. Cl. H05K 7/20

(52) U.S. Cl. CPC H05K 7/20718
USPC 165/104.13

(57) ABSTRACT

A high efficiency Tier IV cooling system architecture and cooling unit for fault tolerant computer room air conditioner systems incorporates a cooling unit which comprises a cold water heat exchange system and a series coupled chilled water heat exchange system. A return air input is coupled to the cold water and chilled water heat exchange systems and a supply air output provides the return air cooled through at least one of the cold water and chilled water heat exchange systems.

### CROSS REFERENCE TO PROVISIONAL PATENT APPLICATION

The present invention is related to, and claims priority from, U.S. Provisional Patent Application Ser. No. 61/665,734 filed Jun. 28, 2012, the disclosure of which is herein specifically incorporated by this reference in its entirety.

### BACKGROUND OF THE INVENTION

The present invention relates, in general, to the field of computer data centers. More particularly, the present invention relates to a high efficiency Tier IV cooling system architecture and cooling unit for fault tolerant computer room air conditioner systems.

The Uptime Institute is a consortium, now owned by the 451 Institute, which has issued guidelines of computer data center tier standards providing a methodology used to determine data availability in a given computer facility. Briefly, Tier I defines a basic (non-redundant) level of availability of 99.67%; Tier II defines an uptime of 99.75% through the utilization of redundant components; Tier III defines an availability of 99.98% for concurrently maintainable systems while, the highest level, Tier IV defines a fault tolerant system with 99.99% availability.

Further information regarding the requisites of the Tier I through Tier IV taxonomy may be found in, for example, Turner IV, W. P. et al., “Tier Classifications Define Site Infrastructure Performance” published as a white paper by the Uptime Institute and “Data Center Site Infrastructure Tier Standard: Topology” published as a data center industry standard, also by the Uptime Institute. As to Tier IV data center criteria in particular, continuous cooling is required. See, for example, Menuet, R. et al., “Continuous Cooling is Required for Continuous Availability” also published as a white paper by the Uptime Institute. The disclosures of the forgoing documents are herein specifically incorporated by this reference in their entirety.

In essence, cooling is critical for the continuous operation of data centers and is subject to two primary quality characteristics, namely energy efficiency and Tier topology quality.

As to the former characteristic, energy efficiency is measured by a Power Usage Effectiveness (PUE) metric which is defined by the ratio of the total power or energy input to the data center divided by the total power or energy being consumed by the Information Technology (IT) equipment in the data center. In this regard, a lower PUE number indicates that the data center is more efficient, with the cooling system being the greatest factor impacting the PUE.

With respect to the latter characteristic of Tier topology, this is a data center quality rating system as previously described. To obtain a rating of Tier IV, the data center must be resilient to unexpected failures of any system or piece of equipment. As previously noted as well, Tier IV topology requires that the cooling to the data center be continuous, that is it cannot be interrupted even when there is an electrical utility outage. It is also required that the cooling units be redundant, with failure modes that are independent. This means that there can be no common failure points across multiple cooling units.

Consequently, it can be seen that it would be distinctly advantageous to provide a highly reliable and energy efficient data center cooling system architecture and cooling unit for the same while meeting Tier IV quality criteria. Moreover, it would further be desirable to provide such advantages implemented through a modular approach throughout the modular build out cycle, to match capacity deployment to demand and to delay capital expenditures to when they are needed.

The data center industry has heretofore implemented Tier IV data centers and has implemented efficient, low-PUE data centers, but none have been implemented incorporating both Tier IV quality and a PUE lower than 1.5. All Tier IV data centers implemented to date have been built with very redundant central cooling systems, which are not energy efficient due to the requisite redundancy, or with independent air cooled chillers or Direct Expansion (DX) cooling units, both of which are not sufficiently energy efficient.

### SUMMARY OF THE INVENTION

In accordance with the high efficiency Tier IV cooling system architecture and cooling unit for fault tolerant computer room air conditioner systems of the present invention, data centers may be designed and built in a modular approach to a very high level of energy efficiency (low PUE) with a concomitantly high level of quality (Tier IV) throughout the entire modular build out cycle.

Particularly disclosed herein is a cooling unit which comprises a cold water heat exchange system and a chilled water heat exchange system coupled in series with the cold water heat exchange system. A return air input is coupled to the cold water and chilled water heat exchange systems and a supply air output provides the return air cooled through at least one of the cold water and chilled water heat exchange systems.

Also particularly disclosed herein is an air conditioning system for a facility which comprises at least one cooling tower having cold water supply and return lines and at least one air cooled chiller having chilled water supply and return lines. A cooling unit having a cold water heat exchange portion is coupled to the cold water supply and return lines and a chilled water heat exchange portion is coupled to the chilled water supply and return lines. A return air input of the cooling unit provides air from the facility to the cold water and chilled water heat exchange portions and a supply air output of the cooling unit provides cooled air to the facility.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIGS. 1A, 1B and 1C illustrate a representative embodiment of a Tier IV cooling system architecture in accordance with a representative embodiment of the present invention implemented in conjunction with a novel Super Computer Room Air Conditioner (Super-CRAC) as disclosed herein.

### DESCRIPTION OF A REPRESENTATIVE EMBODIMENT

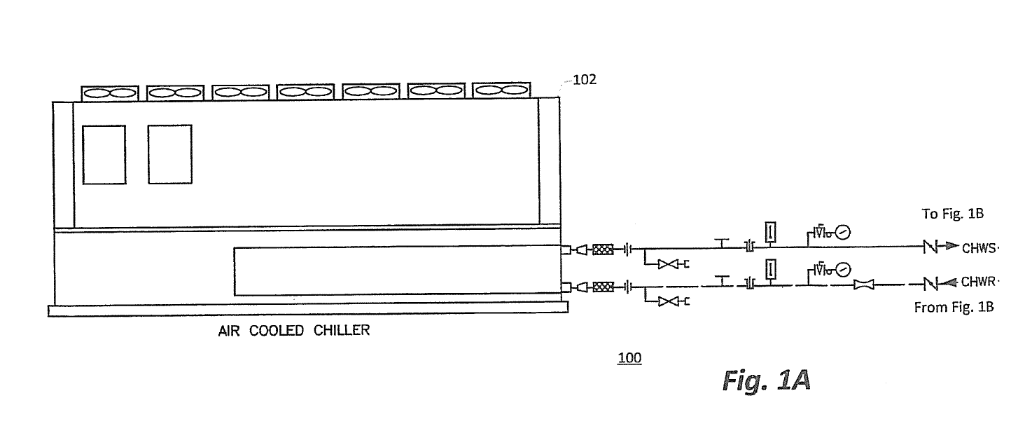

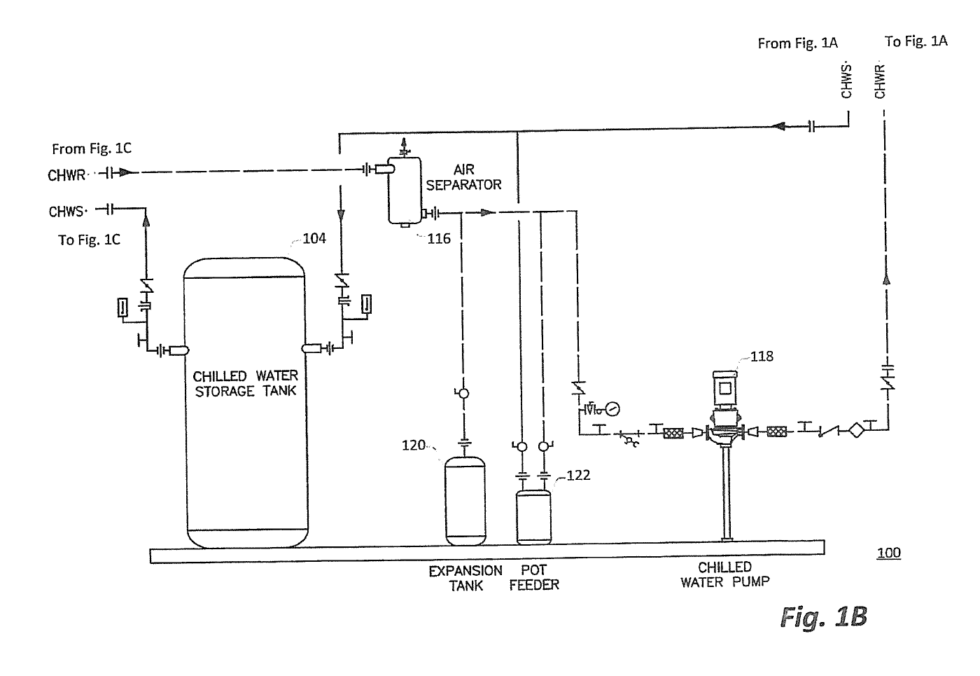

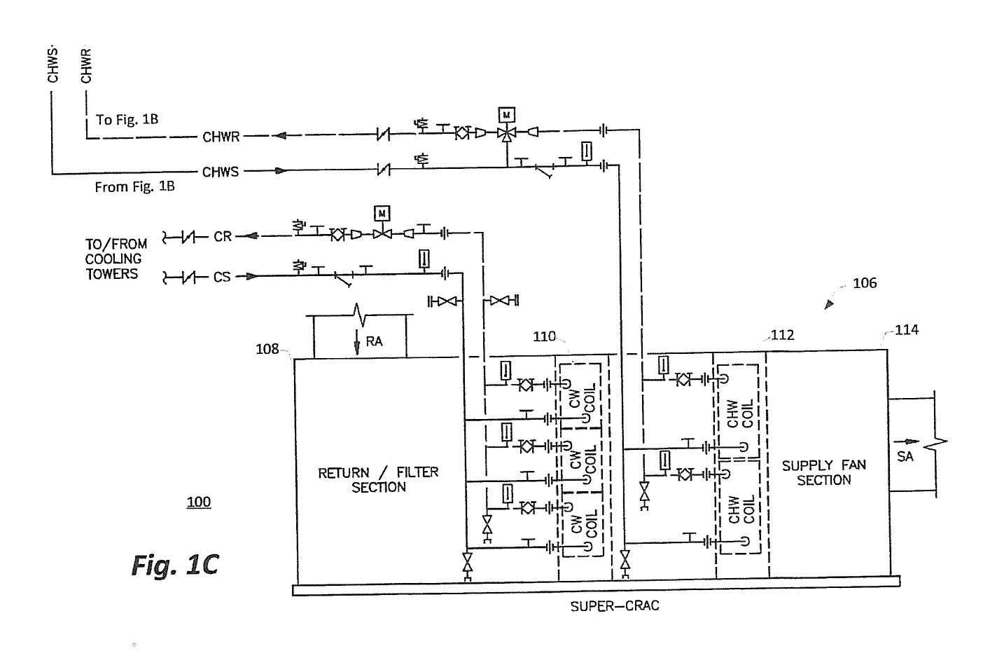

With reference now to FIGS. 1A through 1C inclusive, a representative Tier IV cooling system 100 in accordance with an embodiment of the present invention is shown. The cooling system 100 comprises, in pertinent part, an air cooled chiller 102 (FIG. 1A) for supplying a chilled water supply (CHWS) to a chilled water storage tank 104 as shown in FIG. 1B. In turn, the chilled water storage tank 104 is operative to supply chilled water to the chilled water coil (CHW Coil) heat exchange section 112 of Super-CRAC cooling unit 106 as shown in FIG. 1C.

The chilled water exiting the CHW coil section 112 returns along a chilled water return (CHWR) line to an air separator 116 and pump 118 (FIG. 1B to the air cooled chiller 102 (FIG. 1A). An expansion tank 120 and pot feeder 122 are coupled to the output of the air separator 116 (FIG. 1B) with the pot feeder 122 also coupled to the CHWS output of the air cooled chiller 102.

With particular reference to FIG. 1C, a cold water (CW) coil heat exchange section 110 of the Super-CRAC cooling unit 106 is also coupled to the cold water supply (CS) output of one or more cooling tower(s) (not shown) and the water exiting the CW coil heat exchange section 110 is returned to the cooling tower(s) along a cold water return (CR) line. As illustrated return air (RA) from an associated facility, such as a computer room, enters a return/filter section 108 of the Super-CRAC cooling unit 106 whereupon it passes through the CW coil heat exchange section 110, the CHW coil heat exchange section 112 and into the supply fan section 114 to provide cooled supply air (SA) to the computer room.

Although the representative embodiment of FIGS. 1A through 1C illustrates only a single cooling unit 106, an associated chilled water storage tank 104 and other related equipment, it should be noted that more than one such cooling unit 106, chilled water storage tank 104 and the like may be added to a facility cooling system 100 in a modular fashion as the facility may be expanded at various points in the future. For Tier IV compliance, at least two cooling systems 100 must be in place at a facility.

In accordance with the cooling system 100 of the present invention, the cooling unit 106 pairs a very energy efficient cooling system using cold water free cooling with a very reliable, independent chilled water system using air cooled chillers 102. The overall energy efficiency is extraordinarily high due to the cold water free cooling system that has been designed to operate either concurrently with, or independently from, the chilled water system.

In operation of a cooling system 100 in accordance with the present invention, the data center PUE will be substantially below 1.3, making the data center one of the most energy efficient multi-tenant data centers in the world. The cold water, free cooling system will provide 100% of cooling required for almost all of the hours in a year depending on the data center location and climate. The chilled water system will operate as required for supplemental cooling and when needed for high reliability, as in the case of a utility outage.

The chilled water system of the cooling system 100 enables a Tier IV rating to be achieved due to the following characteristics:

1) Continuous cooling is accomplished through the use of modular thermal storage implemented within each cooling unit 106. Thermal storage is accomplished through the use of a chilled water storage tank 104, which during a utility outage will provide chilled water to the cooling system 100 for the duration of time until utility power or site-generated power is available.

2) Pumps and fans necessary to deliver the cooling from the chilled water storage tank 104 to the data center will run on an uninterruptable power supply (UPS) so the entire cooling system 100 will provide continuous cooling.

3) Each cooling unit 106 will operate completely independently from each other, with an autonomous control system, eliminating the possibility of a common control failure affecting multiple cooling units 106.

4) Each cooling unit 106 will be powered by independent, redundant electricity sources, eliminating the possibility of a common electrical failure affecting multiple cooling units 106.

Previous energy efficient designs rely on large central cooling equipment which is efficient at the ultimate build out but are not as efficient during the typical incremental build out of a data center. The modular aspects of the present invention affords no degradation of either efficiency or reliability throughout the phased build out of the data center.

In an exemplary cooling system 100 in accordance with the present invention (assuming implementation at sea-level), the following cooling characteristics can be achieved with a Super-CRAC cooling unit 106 performance of 70,000 cubic feet/minute (CFM), a supply air (SA) temperature of approximately 70° Fahrenheit (F) and a capacity of substantially 197.9 tons:

Cold Water ΔT=12° F. (e.g. 78° F. entering cooling tower, 66° F. leaving, 394 gallons per minute per Super-CRAC cooling unit 106); and

Chilled Water ΔT=20° F. (e.g. 80° F. entering chiller 102, 60° F. degrees leaving, 237.4 gallons per minute per Super-CRAC cooling unit 106).

While there have been described above the principles of the present invention in conjunction with a specific cooling system architecture and cooling unit apparatus, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

As used herein, the terms “comprises”, “comprising”, or any other variation thereof, are intended to cover a non-exclusive inclusion, such that a process, method, article, or apparatus that comprises a recitation of certain elements does not necessarily include only those elements but may include other elements not expressly recited or inherent to such process, method, article or apparatus. None of the description in the present application should be read as implying that any particular element, step, or function is an essential element which must be included in the claim scope and THE SCOPE OF THE PATENTED SUBJECT MATTER IS DEFINED ONLY BY THE CLAIMS AS ALLOWED. Moreover, none of the appended claims are intended to invoke paragraph six of 35 U.S.C. Sect. 112 unless the exact phrase “means for” is employed and is followed by a participle.

What is claimed is:

1. A cooling unit comprising:
a cold water heat exchange system;
a chilled water heat exchange system coupled in series with said cold water heat exchange system;
a return air input coupled to said cold water and chilled water heat exchange systems; and
a supply air output providing said return air cooled through at least one of said cold water and chilled water heat exchange systems.

2. The cooling unit of claim 1 wherein said cold water heat exchange system comprises at least one cold water coil.

3. The cooling unit of claim 1 wherein said chilled water heat exchange system comprises at least one chilled water coil.

4. The cooling unit of claim 1 wherein said return air input further comprises at least one filter.

5. The cooling unit of claim 1 wherein said source air output comprises at least one supply fan.

6. The cooling unit of claim 1 wherein cold water for said cold water heat exchange system is supplied by at least one cooling tower.

7. The cooling unit of claim 1 wherein chilled water for said chilled water heat exchange system is supplied by at least one air cooled chiller.

8. The cooling unit of claim 7 further comprising:
a tank for storing said chilled water interposed between said air cooled chiller and said chilled water heat exchange system.

9. The cooling unit of claim 1 wherein said cold water heat exchange system and said chilled water heat exchange system are operable separately or together.

10. The cooling unit of claim 1 wherein said cooling unit forms a portion of a Tier IV cooling system.

11. An air conditioning system for a facility comprising:
at least one cooling tower having cold water supply and return lines;
at least one air cooled chiller having chilled water supply and return lines;
a cooling unit having a cold water heat exchange portion coupled to said cold water supply and return lines and a chilled water heat exchange portion coupled to said chilled water supply and return lines;
a return air input of said cooling unit for providing air from said facility to said cold water and chilled water heat exchange portions; and
a supply air output of said cooling unit for providing cooled air to said facility.

12. The air conditioning system of claim 11 wherein said cold water heat exchange portion and said chilled water heat exchange portion are configured in tandem.

13. The air conditioning system of claim 11 wherein said cold water heat exchange portion and said chilled water heat exchange portion are configured in series.

14. The air conditioning system of claim 11 wherein said cold water heat exchange portion and said chilled water heat exchange portion are operable separately or together.

15. The air conditioning system of claim 11 wherein said cold water heat exchange portion and said chilled water heat exchange portion comprise coils through which said air from said facility is passed.

16. The air conditioning system of claim 11 further comprising at least one filter associated with said return air input.

17. The air conditioning system of claim 11 further comprising at least one fan associated with said supply air output.

18. The air conditioning system of claim 11 further comprising a chilled water storage tank interposed on said chilled water supply line between said air cooled chiller and said chilled water heat exchange portion of said cooling unit.

19. The air conditioning system of claim 11 wherein said system is a Tier IV cooling system.
